(19) United States
(12) Patent Application Publication
(10) Pub. No.: US 2008/0290356 A1
(43) Pub. Date: Nov. 27, 2008

(54) Reflective Layered System Comprising a Plurality of Layers that are to be Applied to a III/V Compound Semiconductor Material

(76) Inventors: Gertrud Krauter, Regensburg (DE); Andreas Plossl, Regensburg (DE); Ralph Wirth, Pettendorf-Adlersberg (DE); Heribert Zull, Regensburg (DE)

Correspondence Address: FISH & RICHARDSON PC, P.O. BOX 1022, MINNEAPOLIS, MN, 55440-1022, US

(21) Appl. No.: 11/629,582

(22) PCT Filed: Jun. 29, 2005
(86) PCT No.: PCT/DE2005/001148

§ 371 Date: Dec. 14, 2006

(30) Foreign Application Priority Data
Jun. 30, 2004 (DE) 10 2004 031 684.8
Aug. 19, 2004 (DE) 10 2004 040 277.9

(51) Int. Cl. H01L 33/00; H01L 29/20

(52) U.S. Cl. 257/98; 257/615; 257/E33.023; 257/E29.089

(57) ABSTRACT

The invention describes a method for producing a reflective layer system and a reflective layer system for application to a III/V compound semiconductor material, wherein a first layer, containing phosphosilicate glass, is applied directly to the semiconductor substrate Disposed thereon is a second layer, containing silicon nitride. A metallic layer is then applied thereto.

The invention relates to a reflective layer system comprising a plurality of layers for application to III/V compound semiconductor materials for optoelectronic semiconductor chips.

Reflective layers for deflecting light beams are frequently disposed both on the outer surfaces and in the interior of optoelectronic semiconductor chips, it usually being desirable for such reflective layers to have high reflectivity in all spatial directions. One measure of this the integral reflectivity Rᵢₙₜ. This is the normalized integral of the intensity R(θ) reflected by the layer system over the angular range in which reflection occurs:

$${R}_{int} = {\int }_{0}^{π / 2} R ( ϑ ) sin ϑ d ϑ / {\int }_{0}^{π / 2} sin ϑ d ϑ$$

Reflective layers that exhibit high reflectivity over all solid angles can be obtained through the use not only of pure metal layers, but also of combinations of dielectric layers having a low refractive index and reflective metal layers.

Silicon dioxide, for example, is a material that can be used for the dielectric layer by reason of its refractive index. However, in constructing a reflective layer system based on a III/V compound semiconductor material, silicon dioxide has the disadvantage that its thermal expansion coefficient is very different from that of III/V compound semiconductors, and this can lead to adhesion problems.

The object of the present invention is to specify a reflective layer system with optimized integral reflectivity and optimized stability for application to a III/V compound semiconductor material, and a method for producing same.

These objects are achieved by means of a reflective layer system having the features of claim 1.

Advantageous improvements of the reflective layer system are specified in the dependent claims.

In a reflective layer system according to the invention, a dielectric layer containing phosphosilicate glass (PSG) is disposed on the III/V compound semiconductor surface to be provided with the reflective layer system. The dielectric layer is followed, preferably immediately, by another metallic layer, as viewed looking outward from the III/V compound semiconductor/V compound semiconductor surface. The dielectric layer is preferably situated directly on this III/V compound semiconductor surface.

Other layers, such as for example a gold-containing layer, can also be disposed on the layer system to join the surface of the reflecting layer system to another surface by exposure to pressure and temperature.

Compared to a pure silicon layer, the phosphosilicate-glass-containing dielectric layer has the advantage that its thermal expansion coefficient can be changed by varying the phosphate content. For instance, the thermal expansion coefficient of the dielectric layer can in particular be adapted to the III/V compound semiconductor. This prevents adhesion problems that can occur for example as a result of different thermal expansion coefficients, for example when pure silicon dioxide layers are placed on III/V compound semiconductor surfaces.

At the same time, the refractive index of a layer containing phosphosilicate glass does not differ substantially from that of a pure silicon dioxide layer, as can be learned from the document entitled “Physical properties of phosphorus-silica glass in fiber preforms” (Journal of Communications Technology and Electronics 43, 4, 1998, pp. 480-484), whose disclosure content in this regard is hereby incorporated by reference.

A reflective layer system configured in this way has an optimized integral reflectivity while still possessing adequate mechanical stability.

Additional layers a few molecules thick can also be disposed between the phosphosilicate-glass-containing dielectric layer and the III/V compound semiconductor substrate, for example to promote adhesion.

The reflecting layer system can be also be applied to other materials whose optical properties are similar to those of III/V compound semiconductor materials, such as for example zinc selenide.

An encapsulating layer is preferably disposed between the dielectric layer and the metallic layer to encapsulate the dielectric layer from the chip environment and thus protect it against moisture insofar as possible. Since the phosphate content of phosphosilicate glass makes it strongly hygroscopic, potentially resulting in the formation of phosphoric acid upon contact with water, this can be advisable particularly when the metallic layer cannot be applied directly to the dielectric layer with sufficient promptness for process engineering reasons.

The encapsulating layer preferably contains silicon nitride, not necessarily in stoichiometric proportions, or SiOₓN_{y}, wherein x, y ∈[0; 1] and x+y=1. These materials offer the advantage that they are virtually transparent to the electromagnetic radiation to be reflected and constitute a good adhesion base for a subsequent metallic layer.

In a particularly preferred embodiment of a reflective layer system, the phosphate content of the dielectric layer is selected so that its thermal expansion coefficient is adapted to that of the III/V compound semiconductor material, which advantageously substantially improves the adhesion properties.

In a further particularly preferred embodiment of a reflective layer system, the metallic layer contains at least one material of the group consisting of gold, zinc, silver and aluminum.

It is possible for an additional layer designed to promote adhesion to be disposed under the metallic layer. Such an adhesion promoting layer preferably contains Cr or Ti.

A fourth barrier layer, comprising TiW:N, is preferably disposed on the metal layer of the reflective layer system. TiW:N denotes in this context a layer material formed by applying the materials Ti and W simultaneously to a surface in a nitrogen atmosphere. Alternatively or additionally, barrier layers can also contain Ni, Nb, Pt, Ni:V, TaN or TiN.

The barrier layer has the function of protecting at least individual layers of the underlying reflective layer system against harmful influences from the environment or caused by other processes. For instance, such a layer can be applied for example to protect the reflective layer system against contact with molten metals, which might occur for example during subsequent soldering operations. Alternatively, the barrier layer can also constitute a barrier against moisture from the environment. This is advisable for example when one of the lower layers contains silver, to prevent silver migration.

For purposes of electrical contacting, electrically conductive contact sites are preferably formed through the reflective system and establish an electrically conductive connection from the III/V compound semiconductor material through all the insulating layers. By this means, for example the active layer sequence of a thin-film LED chip can be electrically contacted from the back.

Furthermore, in an advantageous embodiment of the invention, individual layers or all the layers of the reflective layer system can be formed only on subareas of the III/V compound semiconductor surface. The reflective layer system thus is fully formed only where this is required for the operation of the chip. If the III/V compound semiconductor surface is structured, the layers can also be applied in conformity with that structuring.

Particularly preferably, the reflective layer system is applied to a III/V compound semiconductor material based on GaN, GaP or GaAs.

A “III/V compound semiconductor material based on GaN” means in this context that a material so identified preferably contains AlₙGaₘIn₁₋ₙ₋ₘN, where 0≦n≦1, 0≦m≦1 and n+m≦1. This material need not necessarily have a composition that is mathematically exactly that of the above formula. Rather, it can contain one or more dopants or additional constituents that do not substantially alter the characteristic physical properties of the material. For the sake of simplicity, however, the above formula includes only the essential components of the crystal lattice (Al, Ga, In, N), even though these may be partially replaced by trivial amounts of other substances.

A “III/V compound semiconductor material based on GaP” means in this context that a material so identified preferably contains AlₙGaₘIn₁₋ₙ₋ₘP, where 0≦n≦1, 0≦m≦1 and n+m≦1. This material need not necessarily have a composition that is mathematically exactly that of the above formula. Rather, it can contain one or more dopants or additional constituents that do not substantially alter the characteristic physical properties of the material. For the sake of simplicity, however, the above formula includes only the essential components of the crystal lattice (Al, Ga, In, P), even though these may be partially replaced by trivial amounts of other substances.

A “III/V compound semiconductor material based on GaAs” means in this context that a material so identified preferably contains AlₙGaₘIn₁₋ₙ₋ₘAs, where 0≦n≦1, 0≦m≦1 and n+m≦1. This material need not necessarily have a composition that is mathematically exactly that of the above formula. Rather, it can contain one or more dopants or additional constituents that do not substantially alter the characteristic physical properties of the material. For the sake of simplicity, however, the above formula includes only the essential components of the crystal lattice (Al, Ga, In, As), even though these may be partially replaced by trivial amounts of other substances.

Particularly preferably, the reflective layer system according to the invention is suitable for use in a thin-film light-emitting diode chip (thin-film LED chip), since in this case the reflective layer structure is inside the chip, and mechanically stable cohesion of the stack is essential to the operation and reliability of the semiconductor chip.

A thin-film LED chip is distinguished in particular by the following characteristic features:
applied to or configured on a first main surface, facing a carrier element, of an active epitaxial layer sequence able to generate electromagnetic radiation is a reflective layer that reflects at least a portion of the electromagnetic radiation generated in the epitaxial layer sequence back thereinto; and
the epitaxial layer sequence has a thickness in the range of 20 μm or less, particularly in the range of 10 μm.

The epitaxial layer sequence preferably comprises at least one semiconductor layer that has at least one surface with an intermixing structure, which in the ideal case brings about a nearly ergodic distribution of the light in the epitaxially grown epitaxial layer sequence, i.e., said layer has a scattering behavior that is as ergodic as possible.

A basic principle of a thin-layer LED chip is described, for example, in I. Schnitzer et al., Appl. Phys. Lett. 63 (16), Oct. 18, 1993, 2174-2176, whose disclosure content in this regard is hereby incorporated by reference.

A thin-film LED chip is, as a good approximation, a Lambertian surface radiator.

All or some layers of the reflective layer system can be deposited by means of a chemical vapor deposition process (CVD process). This can be for example a plasma-enhanced chemical vapor deposition process (PECVD process) or a low-pressure chemical vapor deposition process (LPCVD process).

Factors affecting the deposition of phosphosilicate glass films are cited in the document Baliga et al., 1973 (B. J. Baliga and S. K. Ghandhi, 1973, J. Appl. Phys. 44, 3, p. 990), whose disclosure content in this regard is hereby incorporated by reference.

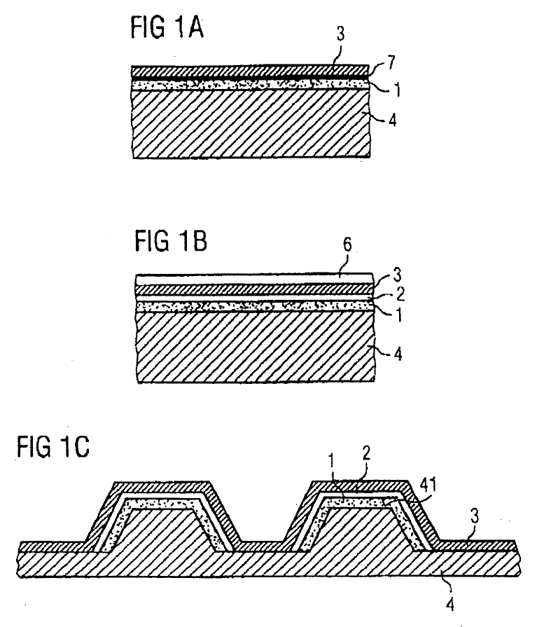

Further advantages, advantageous embodiments and improvements of the reflective layer system and the method for producing same will emerge from the exemplary embodiments described hereinafter, which are explained with reference to FIGS. 1a to 1c, 2a to 2b, 3 and 4.

### Therein:

FIGS. 1a to 1b are schematic sectional diagrams of reflective layer systems on a III/V compound semiconductor surface,

FIG. 1c is a schematic sectional diagram of a reflective layer system on a structured III/V compound semiconductor surface,

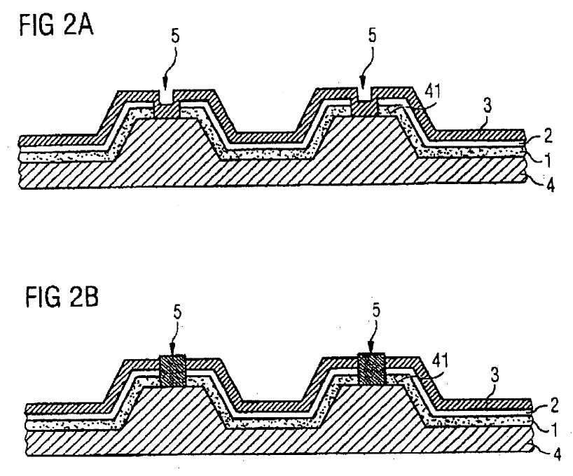

FIGS. 2a to 2b are schematic sectional diagrams of reflective layer systems on a structured III/V compound semiconductor surface comprising various electrical contact sites,

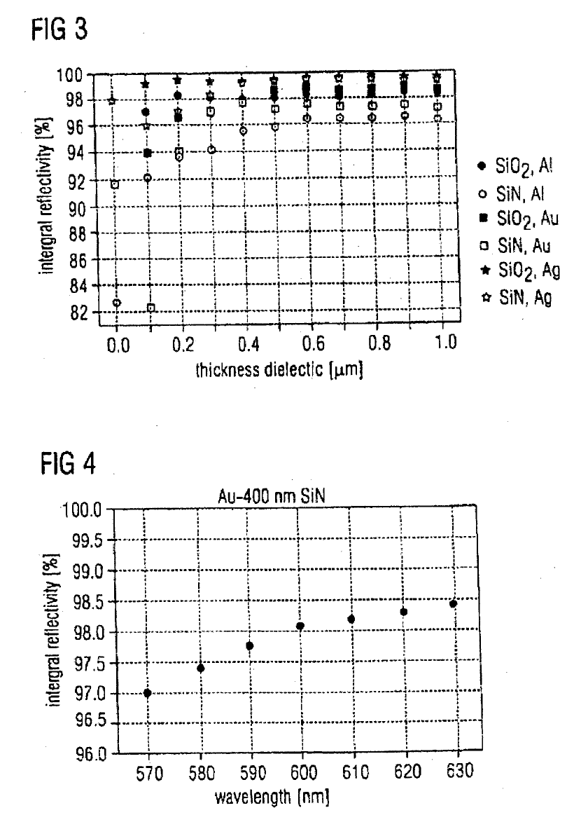

FIG. 3 is a graph in which the integral reflectivities of layer sequences composed of different dielectric and metallic layers on a substrate with a refractive index n=3.4 are plotted as a function of the thickness of the dielectric layer, and

FIG. 4 is a graph in which the integral reflectivity of a layer system containing a dielectric layer of silicon nitride and a metallic layer of gold on a substrate with a refractive index n=3.4 are plotted as a function of the wavelength of the electromagnetic radiation.

In the exemplary embodiments and figures, elements of the same kind or identically acting elements are each provided with the same respective reference numerals. The elements illustrated in the figures, especially the thicknesses of illustrated layers, are not to be considered true-to-scale. They may instead be depicted, in part, as exaggeratedly large for purposes of better understanding.

The reflective layer system according to FIG. 1a comprises, disposed on a III/V compound semiconductor material 4, a dielectric layer 1 of PSG material whose phosphate content is preferably in the range of about 20%, to adapt the thermal expansion coefficient of the dielectric layer 1 to that of the III/V compound semiconductor material 4. The variation of the thermal expansion coefficient of phosphosilicate glass with changes in phosphate content is described in the document B. J. Baliga and S. K. Ghandhi, 1974, IEEE Trans. Electron. Dev., ED21, 7, pp. 410-764, whose disclosure content in this regard is hereby incorporated by reference. Disposed after the dielectric layer 1, as viewed from the III/V compound semiconductor material 4, is a metallic layer 3 containing a metal such as for example gold, zinc, silver and/or aluminum. Typical layer thicknesses in this case are 700 nm for the dielectric layer 1 and 600 nm for the metallic layer 3. An adhesion-promoting layer 7, for example containing Cr or Ti, can be disposed under the metallic layer 3.

In the reflective layer system according to FIG. 1b, disposed between the PSG layer 1 and the metallic layer 3 is an encapsulating layer 2, e.g. composed of silicon nitride or silicon oxynitride, which encapsulates the PSG layer 1 against moisture and other negative environmental influences. Such an encapsulating layer can typically have a thickness of 50 nm.

Yet another layer, containing for example TiW:N, Ni, Nb, Pt, Ni:V, TaN, TiN, can be applied as a barrier layer 6 to the reflective layer system. Such a barrier layer 6 has the function of protecting the reflective layer system or individual layers of the reflective layer system against influences from the environment or subsequent processes.

In particular, TiW:N can be applied to this layer system as a barrier layer 6 having a typical thickness of 200 nm.

The reflective layer system according to FIG. 1c is disposed on a III/V compound semiconductor material structured with truncated pyramids. These are coated with a dielectric layer 1 containing phosphosilicate glass, encapsulated in turn by an encapsulating layer 2. Disposed thereon is a continuous metallic layer 3.

This arrangement results in improved encapsulation of the dielectric layer 1, since the latter has no exposed areas—lateral edges, for example—that might come into contact with moisture from the chip environment. The metallic layer 3 also contributes to the encapsulation of the first layer 1. An optimized mirror effect exerted solely on the truncated pyramids 41 is achieved by means of this layer system.

To electrically contact the III/V compound semiconductor material 4 through the reflective layer system, electrical contact sites 5 can be configured on the truncated pyramids 41. Schematically illustrated by way of example in FIG. 2a are contact sites 5 that are made by etching holes into the dielectric layer 1 and the encapsulating layer 2 and then applying the metallic layer 3. The metallic material thereupon fills the holes vertically at least partially and horizontally over their entire area, thereby electrically conductively connecting the metallic layer 3 to the III/V compound semiconductor substrate 4 throughout.

Alternatively to the described photolithographic structuring method, it is also possible to employ a laser process to produce the contact sites 5. In that case, for example a laser is used to create windows for the contact sites 5 in the dielectric layer 1 and—if present—in the encapsulating layer 2. In the windows, the substrate 4 is exposed. The windows have for example a diameter of 1 μm to 20 μm, and thus contact sites 5 with a diameter of this size form during the subsequent process steps. The metallic layer 3 is then deposited. The metallic material thereupon fills the windows vertically at least partially and horizontally preferably over their entire area, thereby electrically conductively connecting the metallic layer 3 to the III/V compound semiconductor substrate 4 throughout.

FIG. 2b schematically represents a further possible realization of the electrical contact sites 5. In contrast to the contact sites 5 according to the exemplary embodiment of FIG. 2a, the vertical extent of these contact sites 5 is at least equal to the height of the dielectric layer 1 and the encapsulating layer 2.

Such electrical contact sites 5 can be produced for example as described hereinafter.

In a first step, windows for the contact sites 5 are etched into the dielectric layer 1 and the encapsulating layer 2 by means of a structured mask, for example consisting of a photosensitive lacquer layer. The metallic layer 3 is then deposited thereon so that the metallic material fills the windows vertically at least partially and horizontally over their entire area. In a subsequent step, the lacquer layer is removed, for example by means of a suitable solvent, in which process portions of the metallic layer 3 that are located on the lacquer layer are also lifted off so that only the electrical contact sites 5 remain. To complete the reflective layer system the metallic layer 3 can now be applied, providing electrical interconnection among the individual contact sites 5.

Alternatively to structuring the contact sites 5 by means of a photolithographic process, it is also possible in this case to structure the contact sites 5 by means of the above-described laser process.

Reflective layer systems composed of a dielectric layer 1 and a metallic layer 3 on a substrate 4 with a refractive index n=3.4, such as for example a semiconductor material, have a higher integral reflectivity if the dielectric layer 1 is made of silicon dioxide rather than silicon nitride (see FIG. 3). In this case, the substrate 4 can be made for example of a semiconductor material with a refractive index of 3.4.

FIG. 4 shows values of the integral reflectivity as a function of the wavelength of the reflected electromagnetic radiation of a layer system composed of a silicon nitride layer and a gold layer 400 nm thick on a substrate 4 with a refractive index of 3.4, for example made of a semiconductor material. It is to be noted here that the integral reflectivity of the layer system increases with the wavelength of the reflected electromagnetic radiation.

Phosphosilicate glass (dielectric layer 1) can be deposited on the III/V compound semiconductor material by means of a CVD process, such as for example a PECVD process. Gas mixtures used in a PECVD process contain for example pure oxygen or nitrous oxide as an oxygen source, phosphine or trimethyl phosphite as a phosphorus source, and silane, disilane, dichlorosilane, diethylsilane or tetraethoxysilane as a silicon source. Argon or nitrogen can be added as a diluting gas to the respective mixture. Particularly commonly used gas mixtures contain silane, oxygen and phosphine or tetraethoxysilane, oxygen and phosphine. The PSG layer deposited in this way (dielectric layer 1) can be encapsulated in situ with silicon nitride (encapsulating layer 2) in a next process step. In a further step, the metal layer (metallic layer 3) is then applied. Alternatively, an LPCVD process can also be used.

The reflective layer system as described in the exemplary embodiments can be applied to a III/V compound semiconductor material 4 based on GaN, GaAs or GaN and containing for example an active photon emitting layer sequence. The photon emitting active layer sequence can in particular be a thin film LED chip.

A photon emitting active layer sequence can for example comprise a conventional pn junction, a double heterostructure, a single quantum well structure (SQW structure) or a multiple quantum well structure (MQW structure). Such structures are known to those skilled in the art and thus will not be elaborated on herein. In the context of the application, the term “quantum well structure” encompasses any structure in which charge carriers undergo quantization of their energy states by confinement. In particular, the term “quantum well structure” implies no statement as to the dimensionality of the quantization. It therefore includes, among other things, quantum wells, quantum wires and quantum dots and any combination of these structures.

It should be pointed out for the sake of completeness that the invention is not, of course, limited to the exemplary embodiments, but rather, all exemplary embodiments which are based on its fundamental principle as explained in the general section fall within the scope of the invention. It should simultaneously be pointed out that the different elements of the various exemplary embodiments can be combined with one another.

This patent application claims the priorities of German Patent Applications 102004031684.8-11 and 102004040277.9-33, whose disclosure content is hereby incorporated by reference.

The invention is not limited by the description with reference to the exemplary embodiments. Rather, the invention encompasses any novel feature and any combination of features, including in particular any combination of features recited in the claims, even if that feature or combination itself is not explicitly mentioned in the claims or exemplary embodiments.

1. A reflective layer system applied to a III/V compound semiconductor material, the reflective layer system comprising:
a dielectric layer containing phosphosilicate glass and disposed on said III/V compound semiconductor material, and
a layer containing a metal and disposed on said dielectric layer.

2. A reflective layer system as in claim 1, further comprising an encapsulating layer, which is disposed between said dielectric layer and said metallic layer and which encapsulates said dielectric layer against the ingress of moisture from the environment.

3. A reflective layer system as in claim 2, wherein said encapsulating layer contains silicon nitride.

4. A reflective layer system as in claim 2, wherein said encapsulating layer contains SiOₓN_{y}, where x, y ∈[0;1] and x+y=1.

5. A reflective layer system as in claim 1, wherein the phosphate content of said dielectric layer is selected so that the thermal expansion coefficient of said dielectric layer is adapted to that of said III/V compound semiconductor material.

6. A reflective layer system as in claim 1, wherein said metallic layer contains at least one material from the group consisting of gold, zinc, silver and aluminum.

7. The reflective layer system as in claim 1, further comprising an adhesion-promoting layer disposed between said metallic layer and said dielectric layer.

8. The reflective layer system as in claim 7, wherein the adhesion-promoting layer between said metallic layer and said dielectric layer contains Cr or Ti.

9. The reflective layer system as in claim 1, further comprising a barrier layer, disposed on said metallic layer, containing at least one material from the group comprising TiW:N, Ni, Nb, Pt, Ni:V, TaN and TiN.

10. The reflective layer system as in claim 1, wherein electrically conductive contact sites are formed through said reflective layer system and create an electrically conductive connection from said III/V compound semiconductor material to the topmost layer.

11. The reflective layer system as in claim 10, wherein said contact sites are produced by etching.

12. The reflective layer system as in claim 10, wherein said contact sites are produced with the aid of a laser.

13. The reflective layer system as in claim 1, wherein one or more of the layers and/or the surface of said III/V compound semiconductor material is structured.

14. The reflective layer system as in, claim 1 wherein said III/V compound semiconductor material contains at least one material based on GaAs, GaN or GaP.

15. A thin-film light-emitting diode chip, comprising a reflective layer system as in claim 1.

16. A thin-film light-emitting diode chip as in claim 15, further comprising an encapsulating layer, which is disposed between said dielectric layer and said metallic layer and which encapsulates said dielectric layer against the ingress of moisture from the environment.

17. A thin-film light-emitting diode chip as in claim 16, wherein said encapsulating layer contains silicon nitride.

18. A thin-film light-emitting diode chip as in claim 16, wherein said encapsulating layer contains SiOₓN_{y}, where x, y ∈[0;1] and x+y=1.

19. A thin-film light-emitting diode chip as in claim 15, wherein said metallic layer contains at least one material from the group consisting of gold, zinc, silver and aluminum.

20. The thin-film light-emitting diode chip as in claim 15, further comprising a barrier layer, disposed on said metallic layer, containing at least one material from the group comprising TiW:N, Ni, Nb, Pt, Ni:V, TaN and TiN.
